(19) United States
(12) Patent Application Publication
(10) Pub. No.: US 2025/0223721 A1
(43) Pub. Date: Jul. 10, 2025

(54) DOPED PbTiO3 PEROVSKITE SINGLE CRYSTAL SEED AND METHOD FOR PREPARING THE SAME

(71) Applicant: KOREA INSTITUTE OF MATERIALS SCIENCE, Changwon-si (KR)

(72) Inventors: Cheol-Woo AHN, Changwon-si (KR); Jong-Jin CHOI, Busan (KR); Byung-Dong HAHN, Changwon-si (KR); Jung-Hwan KIM, Changwon-si (KR); Young-Kook MOON, Changwon-si (KR); Hyun-Ae CHA, Changwon-si (KR)

(21) Appl. No.: 18/884,526

(22) Filed: Sep. 13, 2024

(30) Foreign Application Priority Data
Jan. 5, 2024 (KR) 10-2024-0002055

(51) Int. Cl. C30B 29/32; C30B 9/12; H10N 30/00

(52) U.S. Cl. CPC C30B 29/32; C30B 9/12; H10N 30/708

(57) ABSTRACT

Disclosed are a doped PbTiO₃ perovskite single crystal seed and a method for preparing the same. The doped perovskite single crystal seed contains Pb, Bi, and Ti, and has a composition of (PbBiₓ)TiO₃, where 0.01≤x≤0.1.

### CROSS REFERENCE TO RELATED APPLICATION

This application claims the benefit of Korean Patent Application No. 10-2024-0002055, filed on Jan. 5, 2024, which is hereby incorporated by reference in its entirety into this application.

### BACKGROUND

### Field

The present disclosure relates to a doped PbTiO₃ perovskite single crystal seed and method for preparing the same.

### Description of Related Art

A piezoelectric device is a device that may convert mechanical energy into electrical energy or, conversely, convert electrical energy into mechanical energy.

Due to its excellent piezoelectric properties, a piezoelectric device is widely applied as a functional device such as transformers, actuators, transducers, sensors, resonators, and filters.

In particular, the demand for a transparent piezoelectric device has been increasing recently.

The transparent piezoelectric device is a future IT device that may be applied to information recognition components such as transparent sensors, transparent RFID tags, and transparent security electronic devices, information processing components such as transparent digital/analog ICs, and information display components such as smart windows and transparent information displays.

A perovskite structure is most commonly employed in the piezoelectric device.

In particular, a composition of the Pb(Zr,Ti)O₃ (PZT) which is a solid solution of PbZrO₃ (PZ) and PbTiO₃ (PT) with lead as a main component is most widely used as each of a dielectric material and a piezoelectric material due to its high dielectric constant and low dielectric loss characteristics.

However, as the piezoelectric properties required for the piezoelectric device are increasing, various studies are being conducted to improve the piezoelectric properties of general the PZT-based piezoelectric ceramic material.

A TGG (Templated Grain Growth) scheme which is one of the most promising methods among the above studies is a scheme of growing polycrystalline powders so as to have an orientation using a highly orientated template-shaped seed, as shown in FIG. 1.

It is known that the piezoelectric properties of the polycrystalline ceramic prepared via the orientation growth in the above TGG scheme are greatly increased due to the orientation growth, compared to the piezoelectric properties of a non-oriented polycrystalline piezoelectric ceramic.

However, in order to apply the above TGG scheme, a highly oriented seed with a composition similar to that of the polycrystalline powder for seed growth should be prepared.

In particular, when the seed is a single crystal, the polycrystals oriented using the above TGG scheme have substantially the same or similar crystallographic orientations.

To prepare the seed in the form of the template, a topochemical process using a multi-stage substitution scheme as a scheme for growing a two-dimensional seed has been used conventionally.

The topochemical process first creates a two-dimensional intermediate, and then creates an initial perovskite structure via substitution of constituent elements of the intermediate.

In preparation of the PZT-based piezoelectric material, it may be advantageous to use PZ, PT or PZT seeds as seeds for TGG. However, it is known that it is difficult to prepare such seeds, such that BaTiO₃ (BT) seeds have been prepared in the topochemical process and used as seeds for TGG.

Recently, preparation of a seed made of a (Na,Bi,Pb)TiO₃ (NBPT) composition similar to PT has been successfully accomplished by the topochemical process. First, a plate of a PbBi₄Ti₄O₁₅ composition was synthesized, and elements constituting the above composition were replaced with other elements to convert the composition into a perovskite structure of a NBPT composition. The reason why not the PbTiO₃ seed but the NBPT composition seed was prepared by the topochemical process is because it is difficult to prepare the PT seed by the topochemical process.

The topochemical process has the advantage of maintaining a two-dimensional shape thermodynamically because the intermediate has a layered structure.

In particular, it is known that it is difficult for the perovskite structure to have a two-dimensional shape in terms of thermodynamic energy, so that the topochemical process has been mainly used.

However, the above-mentioned topochemical process requires a multi-step process and requires multiple heat treatment steps, so that a process time and cost is increased, thereby making it difficult to commercialize the process. Therefore, when the PT seed may be prepared by a molten salt method, which is known as a relatively simple one-step process, the PT seed preparation mat be advantageous for commercialization.

In particular, the seed as prepared by the topochemical process is advantageously prepared in the form of the template, but has the disadvantage of not being a single crystal. However, when the seed is prepared by the molten salt method, which is a simple one-step process, the single crystal seed is generally prepared.

When the seed is prepared in a polycrystalline state, crystal grains with different piezoelectric properties are mixed with each other, thereby making it difficult to control the crystal grains so as to have the best orientation. However, it is easy to control the single crystal seed into the crystal grains to be highly orientated.

In addition, since the single crystal seed is basically transparent, a transparent piezoelectric device may be prepared using the same. Due to the excellent piezoelectric properties unique to the single crystals, a flexible piezoelectric product with excellent piezoelectric properties may be produced by combing the same with a polymer into a composite.

In order to maximize the advantages of the single crystal seed, a method for preparing the PT perovskite seed that may have at least one cross-sectional surface that is perpendicular to at least one axis direction of all three axes constituting an orthogonal coordinate system especially in the perovskite having a tetragonal crystal structure, and further, may have three cross-sectional surfaces that are respectively perpendicular to all three axes constituting the orthogonal coordinate system is necessary.

However, it is difficult to prepare PT in a single crystal state that has a size at which the PT can be used as a device. Thus, it has been known that the PT in a single crystal state that has a size at which the PT can be used as the device has not been reported to date.

### SUMMARY

A purpose of the present disclosure is to provide a doped PT perovskite single crystal seed of a novel composition with excellent orientation.

More specifically, a purpose of the present disclosure is to provide a PT perovskite single crystal seed that may have at least one flat cross-sectional surface that is perpendicular to at least one axis direction of all three axes constituting an orthogonal coordinate system, and further, may have three flat cross-sectional surfaces that are respectively perpendicular to all three axes constituting the orthogonal coordinate system.

Further, a purpose of the present disclosure is to provide a method for preparing a doped PT perovskite single crystal seed that may prepare the doped PT perovskite single crystal seed in one step using a relatively simple process.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A first aspect of the present disclosure for achieving the above purpose provides a doped perovskite single crystal seed comprising Pb, Bi, and Ti, and having a composition of (PbBiₓ)TiO₃, where 0.01≤x≤0.1.

In accordance with some embodiments of the doped perovskite single crystal seed, the seed has rectangular cross-sectional surfaces respectively perpendicular to three axes constituting an orthogonal coordinate system.

In accordance with some embodiments of the doped perovskite single crystal seed, the seed has rectangular cross-sectional surfaces respectively perpendicular to three axes constituting an orthogonal coordinate system, wherein each of the rectangular cross-sectional surfaces is flat.

In accordance with some embodiments of the doped perovskite single crystal seed, the seed has a tetragonal crystal structure and not includes another secondary phase.

In accordance with some embodiments of the doped perovskite single crystal seed, the seed additionally contains Mg, wherein the doped perovskite single crystal seed has a composition of (PbBiₓMg_{y})TiO₃, where 0.01≤x≤0.1 and 0.001≤y≤0.03.

A second aspect of the present disclosure for achieving the above purpose provides a method for preparing a doped perovskite single crystal seed, the method comprising: (a) a step of mixing powders for the doped PbTiO₃ perovskite single crystal seed with each other to prepare a mixture for the single crystal seed, wherein the powders include Pb compound powders at a content of 10 at. %, Bi compound powers at a content of 1 to 1 at. % and Ti compound powders at a content of 10 at. %; (b) a step of drying the mixture for the single crystal seed; (c) a step of calcining the dried mixture for the single crystal seed; (d) a step of milling the calcined doped PbTiO₃; (e) a step of loading salt and the calcined doped PbTiO₃ into a crucible and heat-treating the loaded salt and calcined doped PbTiO₃; and (f) a step of removing a remaining salt therefrom.

In accordance with some embodiments of the method for preparing the doped perovskite single crystal seed, in the step (a), Mg compound powers are further added to the mixture for the single crystal seed, wherein a content ratio of the Pb compound: the Mg compound is 100 at. %: 0.1 to 3 at. %.

In accordance with some embodiments of the method for preparing the doped perovskite single crystal seed, the calcination of the step (c) is maintained at a temperature condition of 600 to 900° C. for 0.5 to 5 hours.

In accordance with some embodiments of the method for preparing the doped perovskite single crystal seed, the heat treatment of the step (e) is maintained at a temperature condition of 800 to 900° C. for 0 to 10 hours.

In accordance with some embodiments of the method for preparing the doped perovskite single crystal seed, in the step (e), the salt is KF or a mixture of KF and KCl, wherein a content of the salt is in a range of 30 to 70 wt % based on a 100 wt % of a total weight of the calcined doped PbTiO₃ and the salt.

A third aspect of the present disclosure for achieving the above purpose provides a piezoelectric device including a perovskite grown using the doped perovskite single crystal seed as described above.

A fourth aspect of the present disclosure for achieving the above purpose provides a functional device including the piezoelectric device as described above.

The present disclosure may provide the doped PT perovskite single crystal seed having the novel composition.

In addition, the doped PT perovskite single crystal seed according to the present disclosure has rectangular flat cross-sectional surfaces that are respectively perpendicular to all three axes constituting the orthogonal coordinate system, thereby providing an effect of improving the piezoelectric properties of the finally produced perovskite device.

Further, the present disclosure may provide the simple method for preparing the doped PT perovskite single crystal seed having the excellent orientation and piezoelectric properties.

In addition to the above-described effects, the specific effects of the present disclosure are described together with the specific details for carrying out the disclosure as set forth below.

### BRIEF DESCRIPTION OF DRAWINGS

FIG. 1 is a schematic diagram of the TGG (Templated Grain Growth) process.

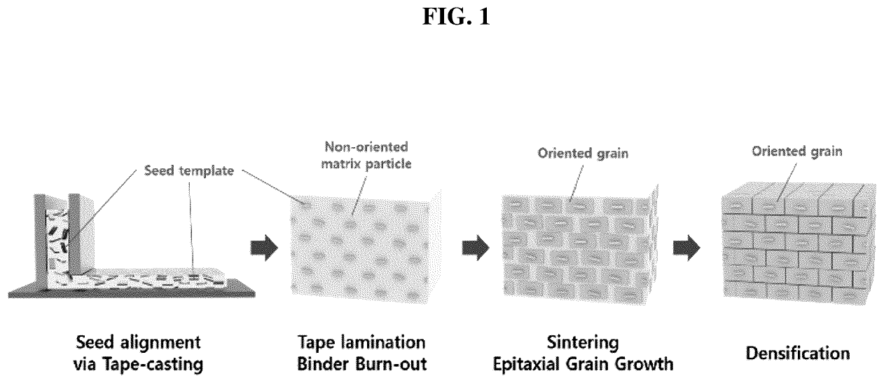

FIG. 2 is a flow chart showing a method for preparing a doped PbTiO₃-based perovskite single crystal seed according to the present disclosure.

FIG. 3 is an SEM image of a single crystal seed as prepared in each of Present Examples 1 to 3 and Comparative Examples 1 and 2 of the present disclosure.

FIG. 4 is an SEM image of a single crystal seed of each of Present Example 2 and Present Example 4 of the present disclosure.

FIG. 5 is an SEM image of each of a seed of Present Example 2, and Present Examples 5 to 7 of the present disclosure.

FIG. 6 is an X-ray diffraction analysis result of a single crystal seed as prepared in the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a perovskite single crystal seed and a method for preparing the same according to some embodiments of the present disclosure will be described.

The molten salt process heat-treats calcined powders and salt at a temperature higher than the temperature at which the salt melts, such that a portion of the calcined powder grows to form a seed.

The molten salt process is a relatively simple one-step scheme. However, a composition condition under which the powder grows into a seed is very strict in this process which in turn is not widely used.

The present disclosure aims to prepare a doped PT-based perovskite single crystal seed using a relatively simple scheme via the molten salt process.

According to the present disclosure, a composition is set by adjusting a content of Bi as a dopant to form a single crystal seed of a doped PT perovskite ceramic.

In particular, the inventors of the present disclosure have identified that when the content (composition range) of Bi in the composition of (PbBiₓ)TiO₃ (_{0.01}≤x≤0.1) varies, a single crystal seed having cross-sectional flat surfaces respectively perpendicular to the three axes of the orthogonal coordinate system is produced only in a specific content of Bi.

When x is 0, a resulting powder having an irregular shape due to the absence of Bi addition and thus not being usable as a single crystal seed may be prepared.

On the other hand, when x is out of the above-mentioned range, irregularly shaped powders may be prepared due to excessive addition of Bi.

In other words, when Bi is not added at all in the seed composition or, conversely, when the content of Bi extends a certain value, irregularly shaped powders that cannot be used as seeds are produced.

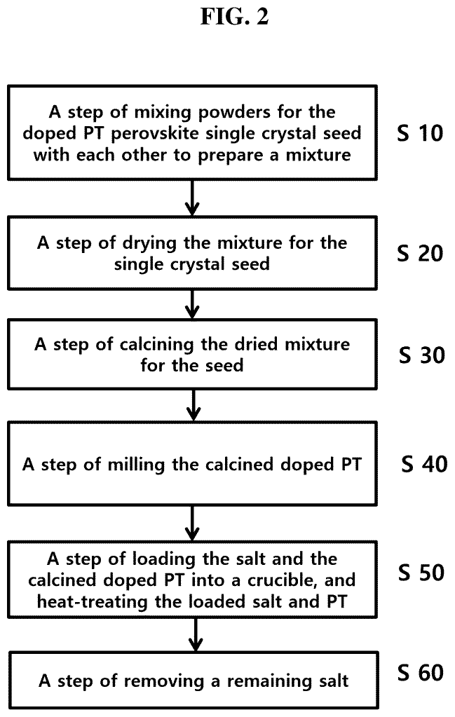

FIG. 2 is a flow chart showing the method for preparing the doped PT-based perovskite single crystal seed according to the present disclosure.

As shown in FIG. 2, the method for preparing the doped PT perovskite single crystal seed according to the present disclosure may include a step S10 of mixing powders for the doped PT perovskite single crystal seed with each other to prepare a mixture, a step S20 of drying the mixture for the single crystal seed, a step S30 of calcining the dried mixture for the seed, a step S40 of milling the calcined doped PT, a step S50 of loading the salt and the calcined doped PT into a crucible, and heat-treating the loaded salt and PT, and a step S60 of removing a remaining salt.

First, the mixture for the doped PT perovskite seed and the salt are prepared.

In order to prepare the mixture for the doped PT perovskite seed, a step of mixing a precursor including a Pb-containing compound, a precursor including a Bi-containing compound, and a precursor including a Ti-containing compound with each other is performed.

The step of mixing the precursors may include weigh each of the precursors respectively containing the respective compounds according to a composition ratio so as to have the composition for the doped PT perovskite seed. In this regard, the Bi-containing compound, the Pb-containing compound, and the Ti-containing compound are respectively contained at 1 to 10 at. %, 100 at. %, and 100 at. %, and may be mixed in the wet milling manner.

At this time, a solvent may be used and does not need to be particularly limited. In one example, the solvent may include distilled water, alcohol, propanol, etc.

In a non-limiting and specific example, the Bi-containing compound may be Bi₂O₃, the Pb-containing compound may be PbO, and the Ti-containing compound may be TiO₂.

However, the present disclosure may not be limited thereto. Other materials than the compounds as presented above may be used as the Bi-containing compound, the Pb-containing compound, and the Ti-containing compound.

In a non-limiting and specific example of the mixing process using the wet milling, the precursors may be mixed with each other for 0.5 to 72 hours using a ball mill. The precursor mixing time is not particularly limited as long as the precursors may be sufficiently mixed with each other.

Thereafter, the mixed precursors may be dried in a dry oven.

The dried precursors are calcined via a calcination process.

In a non-limiting and specific example of the above calcination process, the calcination may be performed at 600 to 900° C. for 0.5 to 5 hours.

The calcined precursors may be milled again using a ball mill within 72 hours as needed. In other words, the calcined precursors may not be milled, or even when being milled, the calcined precursors may be milled for a milling time of less than 72 hours.

Thereafter, the mixture for the doped PT perovskite seed and the salt are loaded into the crucible and then heat-treated therein.

In a non-limiting and specific example, the salt may include at least one of KF and KCl.

With respect to a 100 wt % of a total weight of the mixture for the doped PT perovskite seed and the salt, the salt may be contained in a range of 30 to 70 wt %.

When the content of the salt is smaller than 30 wt %, liquid formation may be insufficient, thereby making it difficult to sufficiently wet the calcined powder during the heat treatment process.

On the other hand, when the content of the salt exceeds 70 wt %, contact between the calcined powders may be hindered.

Next, the above-mentioned mixed mixture is heat-treated to prepare the Pb-based perovskite seed having a composition of (PbBiₓ)TiO₃, where _{0.01}≤x≤0.1.

The above-mentioned heat treatment may be performed at 800 to 900° C. for 0 to 10 hours.

The zero time duration corresponds to a time point set to the heat treatment equipment. In a heat treatment process, the heat treatment equipment reaches the heat treatment temperature and then, a temperature immediately decreases without a maintaining time of the heat treatment temperature.

When the above-mentioned heat treatment temperature is lower than 800° C., the liquid phase formation of the molten salt is not sufficient and the crystal growth may be insufficient.

On the contrary, when the above-mentioned heat treatment temperature exceeds 900° C., the seed growth is not efficient compared to the increase in energy required for the heat treatment.

Next, the Pb-based seed is washed to remove the remaining salt.

The non-limiting and specific removal of the remaining salt may be performed in a scheme in which the salt cooled after the heat treatment is acid-treated with a mixture of water and about 60% nitric acid solution at 50 to 85° C. and then washed with distilled water.

In the salt removal process, the remaining salt may be removed by reacting with the acid and then, selectively dissolving in distilled water in a distilled water washing process.

The washing may be performed at least once, and may be performed by various schemes such as filtering, centrifugation, and stirrer.

The doped PT perovskite single crystal seed as prepared according to the preparing method in accordance with the present disclosure has a composition of (PbBiₓ)TiO₃ (_{0.01}≤x≤0.1).

The finally produced result, that is, the doped PT perovskite single crystal seed has a perovskite (ABO₃) structure in which Pb and Bi located at the A site, and Ti located at the B site.

The doped PT perovskite seed according to the present disclosure may have a tetragonal crystal structure.

In particular, the doped PT perovskite single crystal seed according to the present disclosure may have rectangular flat cross-sectional surfaces respectively perpendicular to all three axes constituting the orthogonal coordinate system, depending on the content (composition range) of the dopant.

For example, the doped PT perovskite single crystal seed according to the present disclosure may have rectangular cross-sectional surfaces respectively perpendicular to the x-axis, y-axis, or z-axis directions constituting the orthogonal coordinate system, depending on the content (composition range) of the dopant, wherein each of the rectangular cross-sectional surfaces is flat.

The specific Present Example of each of the doped PT perovskite single crystal seed and the preparation method thereof as described above will be described as follows.

### Preparing Pb-Based Perovskite Seeds

### Present Example 1: Preparing a Perovskite Single Crystal Seed With a Composition of (PbBi_{0.01})TiO₃

Bi₂O₃ was used as a Bi-containing compound, PbO was used as a Pb-containing compound, and TiO2 was used as a Ti-containing compound. The weights of the powders of the Bi₂O₃ as a Bi-containing compound, PbO as a Pb-containing compound, and TiO2 as a Ti-containing compound as used to prepare the single crystal seed of Present Example 1 were respectively PbO 223.199 g, Bi₂O₃ 2.329785 g, and TiO₂ 79.865 g, and a content ratio of the components Bi:Pb:Ti constituting the seed was 0.01:1:1.

The above PbO+TiO₂+B₂O₃ powders were mixed with each other for 24 hours using a ball mill and then dried in a dry oven.

The above dried powders mixture was calcined at 700° C. for 2 hours to form (PbBi_{0.01})TiO₃ perovskite.

The calcined (PbBi_{0.01})TiO₃ perovskite powders were pulverized and mixed with each other again using a ball mill for 24 hours.

The salt (KF or KF+KCl) and the above (PbBi_{0.01})TiO₃ perovskite powders were placed into an Al₂O₃ crucible and then heat-treated therein at 850° C. for 1 hour.

The above heat-treated (PbBi_{0.01})TiO₃ perovskite powders were washed with a mixture of water and 60% pure nitric acid (water:nitric acid=4:1) at 80° C. using a stirrer at 300 rpm.

### Present Example 2: Preparing a Perovskite Single Crystal Seed With a Composition of (PbBi_{0.05})TiO₃

The single crystal seed of Present Example 2 was prepared under the same conditions and in the same manner as in Present Example 1 except that the weights of the component powders used to prepare the single crystal seed of Present Example 2 were respectively PbO 223.199 g, Bi₂O₃ 11.64893 g, and TiO₂ 79.865 g, and the content ratio of the components Bi:Pb:Ti constituting the seed was 0.05:1:1.

### Present Example 3: Preparing a Perovskite Single Crystal Seed With a Composition of (PbBi_{0.10})TiO₃

The single crystal seed of Present Example 3 was prepared under the same conditions and in the same manner as in Present Example 1 except that the weights of the component powders used to prepare the single crystal seed of Present Example 3 were respectively PbO 223.199 g, Bi₂O₃ 23.29785 g, and TiO₂ 79.865 g, and the content ratio of the components Bi:Pb:Ti constituting the seed was 0.10:1:1.

### Present Example 4: Preparing a Perovskite Single Crystal Seed With a Composition of (PbBi_{0.05})TiO₃

The single crystal seed of Present Example 4 was prepared under the same conditions and in the same manner as in Present Example 2 except that a MgO crucible was used in comparison with Present Example 2.

### Comparative Example 1: Preparing a Perovskite Seed With a Composition of PbTiO₃

The single crystal seed of Comparative Example 1 was prepared under the same conditions and in the same manner as in Present Example 1 except that the weights of the component powders used to prepare the single crystal seed of Comparative Example 1 were respectively PbO 223.199 g and TiO₂ 79.865 g, and the content ratio of the components Bi:Pb:Ti constituting the seed was 0:1:1.

### Comparative Example 2: Preparing a Perovskite Seed Having a Composition of (PbBi_{0.20})TiO₃

The single crystal seed of Comparative Example 2 was prepared under the same conditions and in the same manner as in Present Example 1 except that the weights of the component powders used to prepare the single crystal seed of Comparative Example 1 were respectively PbO 223.199 g, Bi₂O₃ 46.5957 g, and TiO₂ 79.865 g, and the content ratio of the components Bi:Pb:Ti constituting the seed is 0.20:1:1.

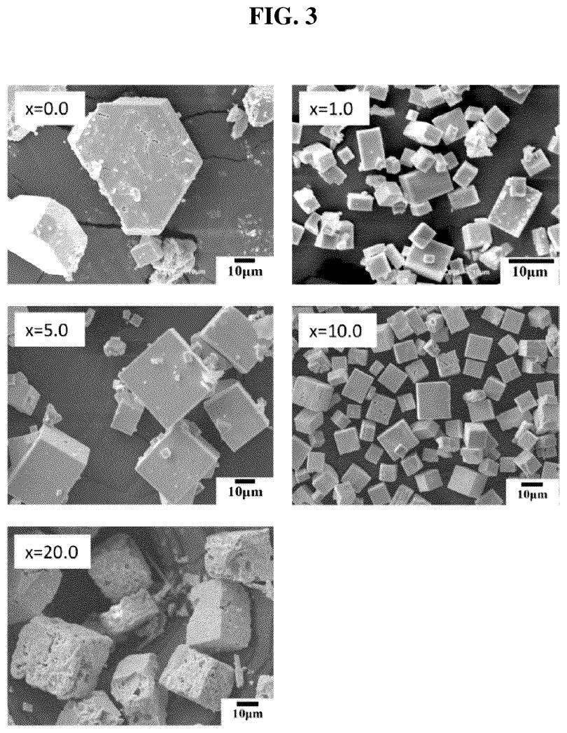

FIG. 3 is an SEM image of the seed as prepared in each of Present Examples 1 to 3 of the present disclosure and Comparative Examples 1 and 2.

As shown in FIG. 3, it may be identified that the doped PT perovskite single crystal seed according to each of Present Examples 1 to 3 of the present disclosure has rectangular cross-sectional surfaces respectively perpendicular to all of three axes, that is, the x-axis, y-axis, or z-axis directions constituting the orthogonal coordinate system, wherein each of the rectangular cross-sectional surfaces is flat.

On the other hand, it may be identified that the doped PT perovskite single crystal seed according to each of Comparative Examples 1 and 2 has a rectangular cross-sectional surface perpendicular to only one axis, and has no rectangular cross-sectional surface perpendicular to any one of the x-axis, y-axis, or z-axis directions constituting the orthogonal coordinate system.

It is determined that the results of the above Present Examples 1 to 3 of the present disclosure are due to the occurrence of abnormal grain growth in which grain growth in a specific orientation is dominant over grain growth in other orientations.

In other words, it is determined that, based on the comparing result between the Present Examples 1 to 3 and Comparative Examples 1 and 2 of the present disclosure with each other, abnormal grain growth due to excessive substitution of Pb with Bi as the donor is promoted in a specific composition range such that the perovskite seed with the composition Bi(_{0.01} to _{0.1}) PbTiO₃ is formed as a single crystal seed.

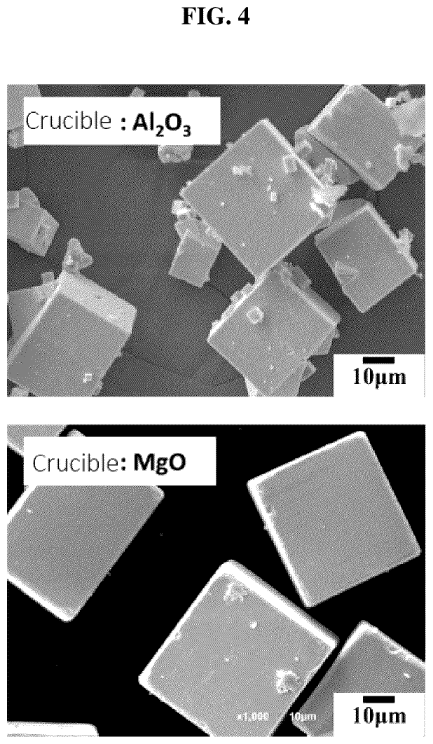

FIG. 4 is an SEM image of the single crystal seed of each of Present Example 2 (Al₂O₃ crucible) and Present Example 4 (MgO crucible) of the present disclosure.

It may be identified that the seed of each of Present Example 2 and Present Example 4 of the present disclosure has rectangular cross-sectional surfaces respectively perpendicular to all of three axes, that is, the x-axis, y-axis, or z-axis directions constituting the orthogonal coordinate system, wherein each of the rectangular cross-sectional surfaces is flat.

However, it may be identified that the single crystal seed of Present Example 4 has a clean surface without any adsorption or attachment of other microcrystals on the surface after washing thereof, compared to Present Example 2.

The results of FIG. 4 suggest that the excellent surface properties of the single crystal seed according to the present disclosure may be obtained due to the addition of Mg.

### Present Example 5: Preparing a Perovskite Single Crystal Seed With a Composition of (PbBi_{0.05}Mg_{0.001})TiO₃

The single crystal seed of Present Example 5 was prepared under the same conditions and in the same manner as in Present Example 1 except that the weights of the component powders used to prepare the single crystal seed of Present Example 5 were respectively PbO 223.199 g, Bi₂O₃ 11.64893 g, TiO₂ 79.865 g, and MgO 0.040304 g, and the content ratio of the components Bi:Pb:Mg:Ti constituting the seed was 0.05:1:0.001:1.

### Present Example 6: Preparing a Perovskite Single Crystal Seed With a Composition of (PbBi_{0.05}Mg_{0.01})TiO₃

The single crystal seed of Present Example 6 was prepared under the same conditions and in the same manner as in Present Example 1 except that the weights of the component powders used to prepare the single crystal seed of Present Example 6 were respectively PbO 223.199 g, Bi₂O₃ 11.64893 g, TiO₂ 79.865 g, and MgO 0.40304 g, and the content ratio of the components Bi:Pb:Mg:Ti constituting the seed was 0.05:1:0.01:1.

### Present Example 7: Preparing a Perovskite Single Crystal Seed With a Composition of (PbBi_{0.05}Mg_{0.03})TiO₃

The single crystal seed of Present Example 7 was prepared under the same conditions and in the same manner as in Present Example 1 except that the weights of the component powders used to prepare the single crystal seed of Present Example 7 were respectively PbO 223.199 g, Bi₂O₃ 11.64893 g, TiO2 79.865 g, and MgO 1.20912 g, and the content ratio of the components Bi:Pb:Mg:Ti constituting the seed was 0.05:1:0.03:1.

### Comparative Example 3: Preparing a Perovskite Seed With a Composition of (PbBi_{0.05}Mg_{0.05})TiO₃

The single crystal seed of Comparative Example 3 was prepared under the same conditions and in the same manner as in Present Example 1 except that the weights of the component powders used to prepare the single crystal seed of Comparative Example 3 were respectively PbO 223.199 g, Bi₂O₃ 11.64893 g, TiO₂ 79.865 g, and MgO 2.0152 g, and the content ratio of the components Bi:Pb:Mg:Ti constituting the seed was 0.05:1:0.05:1.

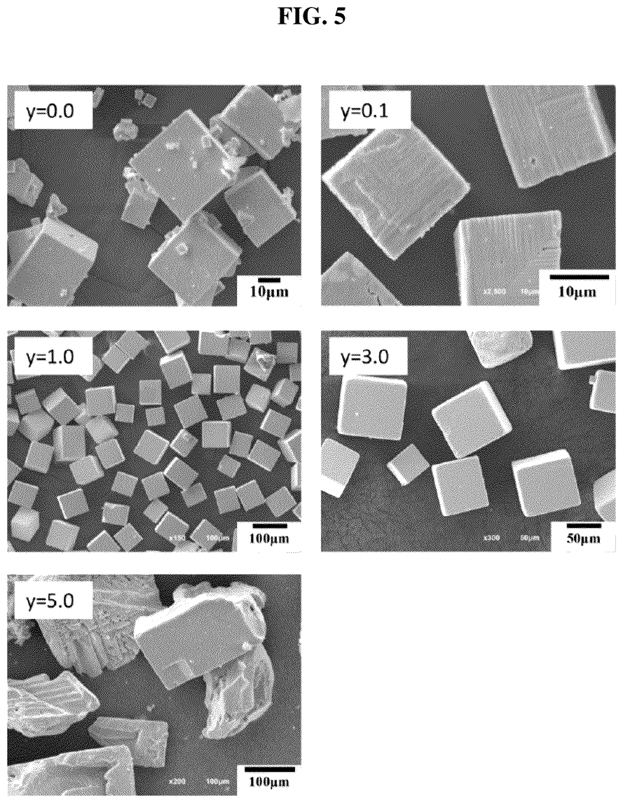

FIG. 5 is an SEM image of the seeds of each of Present Example 2, and Present Examples 5 to 7 of the present disclosure.

As shown in FIG. 5, it may be identified that the seed of each of Present Example 2, Present Example 5 to 7 of the present disclosure has rectangular cross-sectional surfaces respectively perpendicular to all of three axes, that is, the x-axis, y-axis, or z-axis directions constituting the orthogonal coordinate system, wherein each of the rectangular cross-sectional surfaces is flat.

However, it may be identified that the seed of each of Present Example 5 to 7 of the present disclosure has a clean surface without any other microcrystals adsorbed or attached to the surface thereof after several washings, compared to the seed of Present Example 2.

On the other hand, it may be identified that in the seed of Comparative Example 3 of the present disclosure in which Mg is added at 5 at. %, not only is the single crystal seed itself not formed, but also the seed has no rectangular cross-sectional surface perpendicular to any one of the x-axis, y-axis, or z-axis directions constituting the orthogonal coordinate system.

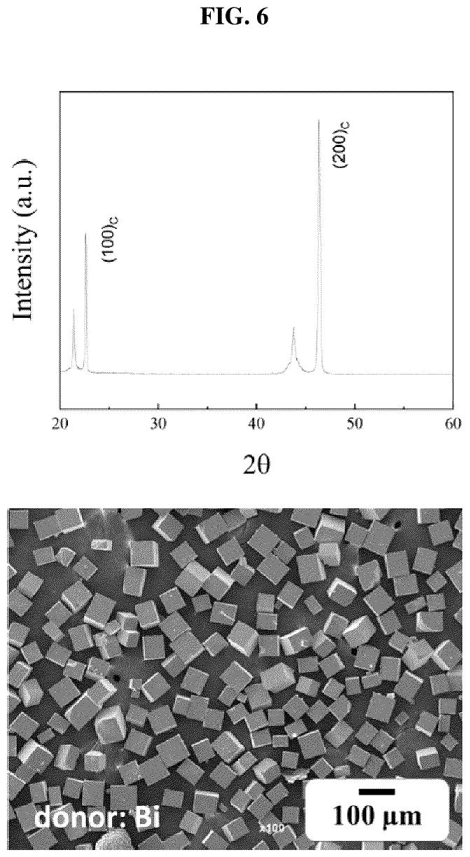

FIG. 6 shows the XRD and SEM observation results of the perovskite single crystal seed with the composition of (PbBi_{0.04}Mg_{0.01})TiO₃.

As shown in FIG. 6, it is identified from the XRD result that the perovskite single crystal seed with the composition prepared in accordance with the present disclosure has a tetragonal crystal structure, and does not contain any other secondary phases, and furthermore, is a single crystal.

Therefore, when the perovskite is grown on the rectangular single crystal seed as prepared according to each of Present Examples of the present disclosure in a subsequent process, a subsequent perovskite component should be oriented in a specific direction on the rectangular single crystal seed to increase the possibility at which growth continues.

In particular, when the single crystal seed according to the present disclosure is applied to the TGG process having the orientation of the particles, the crystal grains grown in a specific orientation of the single crystal seed according to the present disclosure in a subsequent process have substantially the same orientation, so that the final product may exhibit piezoelectric characteristics that are the same as or similar to that of the single crystal even though the product is in a polycrystal state.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A doped perovskite single crystal seed comprising Pb, Bi, and Ti, and having a composition of (PbBiₓ)TiO₃, where 0.01≤x≤0.1.

2. The doped perovskite single crystal seed of claim 1, wherein the seed has rectangular cross-sectional surfaces respectively perpendicular to three axes constituting an orthogonal coordinate system.

3. The doped perovskite single crystal seed of claim 1, wherein the seed has rectangular cross-sectional surfaces respectively perpendicular to three axes constituting an orthogonal coordinate system, wherein each of the rectangular cross-sectional surfaces is flat.

4. The doped perovskite single crystal seed of claim 1, wherein the seed has a tetragonal crystal structure and not includes another secondary phase.

5. The doped perovskite single crystal seed of claim 1, wherein the seed additionally contains Mg,
wherein the doped perovskite single crystal seed has a composition of (PbBiₓMg_{y})TiO₃, where 0.01≤x≤0.1 and 0.001≤y≤0.03.

6. A method for preparing a doped perovskite single crystal seed, the method comprising:
(a) a step of mixing powders for the doped PbTiO₃ perovskite single crystal seed with each other to prepare a mixture for the single crystal seed, wherein the powders include Pb compound powders at a content of 10 at. %, Bi compound powers at a content of 1 to 1 at. % and Ti compound powders at a content of 10 at. %;
(b) a step of drying the mixture for the single crystal seed;
(c) a step of calcining the dried mixture for the single crystal seed;
(d) a step of milling the calcined doped PbTiO₃;
(e) a step of loading salt and the calcined doped PbTiO₃ into a crucible and heat-treating the loaded salt and calcined doped PbTiO₃; and
(f) a step of removing a remaining salt therefrom.

7. The method for preparing the doped perovskite single crystal seed of claim 6, wherein in the step (a), Mg compound powers are further added to the mixture for the single crystal seed,
wherein a content ratio of the Pb compound: the Mg compound is 100 at. %: 0.1 to 3 at. %.

8. The method for preparing the doped perovskite single crystal seed of claim 6, wherein the calcination of the step (c) is maintained at a temperature condition of 600 to 900° C. for 0.5 to 5 hours.

9. The method for preparing the doped perovskite single crystal seed of claim 6, wherein the heat treatment of the step (e) is maintained at a temperature condition of 800 to 900° C. for 0 to 10 hours.

10. The method for preparing the doped perovskite single crystal seed of claim 6, wherein in the step (e), the salt is KF or a mixture of KF and KCl,
wherein a content of the salt is in a range of 30 to 70 wt % based on a 100 wt % of a total weight of the calcined doped PbTiO₃ and the salt.

11. A piezoelectric device including a perovskite grown using the doped perovskite single crystal seed of claim 1.

12. A functional device including the piezoelectric device of claim 11.
